(19) United States
(12) Patent Application Publication
(10) Pub. No.: US 2006/0228894 A1
(43) Pub. Date: Oct. 12, 2006

(54) Method for semiconductor manufacturing using a negative photoresist with thermal flow properties

(75) Inventors: Bang-Ching Ho, Hsin-Chu (TW); Jen-Chieh Shih, Yongkang City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/095,216

(22) Filed: Mar. 31, 2005

(51) Int. Cl. H01L 21/47

(52) U.S. Cl. 438/725; 438/780; 438/781

(57) ABSTRACT

Provided is a method for manufacturing a semiconductor device. In one example, the method includes forming a negative photoresist layer over an underlying layer, where the negative photoresist layer is soluble by a developer when formed. The negative photoresist layer is patterned using a chromium-less mask. The patterning alters at least a portion of the negative photoresist layer so that the altered portion is not soluble by the developer. The patterned negative photoresist layer is developed to form at least one opening in the negative photoresist layer by removing an unaltered portion of the negative photoresist layer. The negative photoresist layer is then heated, which causes the negative photoresist layer to flow.

### BACKGROUND

An integrated circuit (IC) is formed by creating one or more devices (e.g., circuit components) on a semiconductor substrate using a fabrication process. As fabrication processes and materials improve, semiconductor device geometries have continued to decrease in size since such devices were first introduced several decades ago. For example, current fabrication processes are producing devices having geometry sizes (e.g., the smallest component (or line) that may be created using the process) of 90 nm and below. However, the reduction in size of device geometries introduces new challenges in materials and fabrication processes that need to be overcome.

### BRIEF DESCRIPTION OF THE DRAWINGS

FIG. 1 is a flowchart of one embodiment of a method that may use a negative photoresist with thermal flow properties to manufacture a portion of a semiconductor device.

FIG. 2 is a sectional view of one embodiment of a device after the formation of a polymer layer according to the method of FIG. 1.

FIG. 3 is a sectional view of the device of FIG. 2 undergoing a patterning process of the polymer layer according to the method of FIG. 1.

FIG. 4 is a sectional view of the device of FIG. 2 after the polymer layer has been developed according to the method of FIG. 1.

FIG. 5 is a sectional view of the device of FIG. 2 after the polymer layer has been heated according to the method of FIG. 1.

FIG. 6 is a sectional view of the device of FIG. 2 after a layer underlying the polymer layer has been etched according to the method of FIG. 1.

FIG. 7 is a sectional view of the device of FIG. 2 after remaining portions of the polymer layer have been removed according to the method of FIG. 1.

FIG. 8 is a sectional view of one embodiment of an integrated circuit device constructed according to aspects of the present disclosure.

### DETAILED DESCRIPTION

This disclosure relates generally to semiconductor manufacturing and, more particularly, to a system and method for semiconductor manufacturing using a negative photoresist with thermal flow properties.

It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

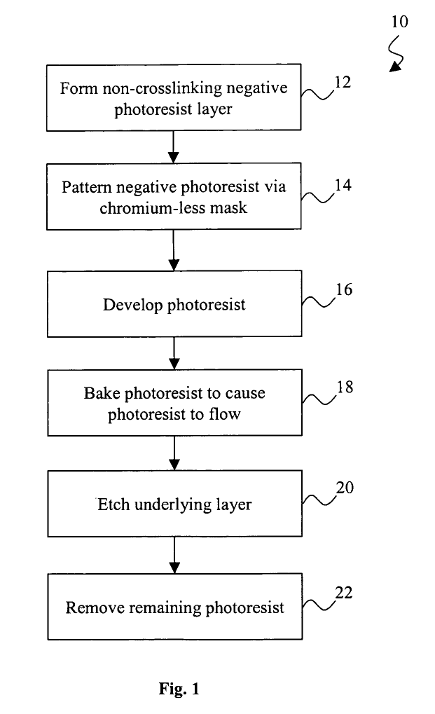

Referring to FIG. 1, in one embodiment, a method 10 illustrates the use of a cr-less mask with a negative photoresist that has thermal flow properties. The following description makes additional reference to FIGS. 2-7, which illustrate a semiconductor device undergoing various manufacturing steps using the method 10 of FIG. 1.

Semiconductor manufacturing processes generally use either positive or negative photoresist during photolithographic processing. Positive photoresist, which may have thermal flow capabilities, is often used in high-resolution patterning. The thermal flow capability enables positive photoresist to flow when it undergoes baking. However, while the use of positive photoresist may increase the depth of focus (DOF) (e.g., a distance along an optical axis over which features of an illuminated surface are in focus during a photolithographic process), it may also increase the mask error factor (MEF). The MEF may be viewed as the ratio of the critical dimension (CD) change on a wafer to the CD error on the mask (reduced to its 1× value), where a CD is the dimension of the smallest geometrical features (such as width of interconnect lines, contacts, and trenches) which can be formed during semiconductor manufacturing using a given technology.

Negative photoresists are typically used in manufacturing situations where manufacturing throughput and cost are paramount issues (e.g., in the fabrication of printed wiring boards). However, negative photoresists generally illustrate cross-linking when exposed to certain wavelengths of light (e.g., they are photochemically rearranged to form new insoluble products). Cross-linking may be further strengthened during a post-exposure baking process. This cross-linking prevents the negative photoresist from having the thermal flow capability of the positive photoresist and may also make the negative photoresist insoluble to many developing agents. This means that the negative photoresist may have an improved MEF compared to positive photoresist, but does not provide an improved DOF that may be gained by using a flowable resist. In addition, it may be difficult to etch the negative photoresist after cross-linking occurs.

While negative photoresist may be used with a chromium-less (Cr-less) mask, the negative photoresist used generally exhibits cross-linking when exposed and therefore does not flow. The use of a cr-less mask with a flowable positive photoresist is generally not satisfactory because a cr-less mask is transparent and works on the principle of destructive interference, making it difficult to form holes when used with positive photoresist.

Accordingly, in step 12 of FIG. 1 and with additional reference to FIG. 2, a polymer layer 106 is formed over an underlying layer 104 and a substrate 102. It is understood that the underlying layer 104 was formed on the substrate 102 prior to the beginning of the method 10.

The substrate 102 may comprise an elementary semiconductor (such as crystal silicon, polycrystalline silicon, amorphous silicon and germanium), a compound semiconductor (such as silicon carbide and gallium arsenic), an alloy semiconductor (such as silicon germanium, gallium arsenide phosphide, aluminum indium arsenide, aluminum gallium arsenide and gallium indium phosphide) and/or any combination thereof. The substrate 102 may also comprise a semiconductor material on an insulator, such as silicon-on-insulator (SOI), or a thin film transistor (TFT). In one embodiment, the substrate 102 may also include a doped epitaxial layer. The substrate 102 may also include a multiple silicon structure or a multilayer, compound semiconductor structure.

The underlying layer 104 (which may represent multiple layers and/or structures) may be formed by thermal oxidation, atomic layer deposition (ALD), chemical vapor deposition (CVD), physical vapor deposition (PVD), plasma enhanced CVD (PECVD), and/or other processes. Moreover, although not limited by the scope of the present disclosure, the underlying layer 104 may comprise one or more different materials of various thicknesses, where the material and/or thickness is based on the purpose of the underlying layer.

The polymer layer 106 may be formed using a process such as spin-on coating. For example, the underlying layer 104 may be coated with a flowable polymer material. The substrate 102 is then rapidly rotated, which uniformly distributes the polymer material on the surface of the underlying layer 104 due to centrifugal forces. The polymer material is then solidified by a low temperature baking process to form the polymer layer 106.

The polymer layer 106 is a negative photoresist that has thermal flow properties. More specifically, the polymer layer 106 does not exhibit cross-linking (or exhibits minimal cross-linking) after exposure and is able to flow when heated to a certain temperature (e.g., during a baking process). In the present embodiment, the polymer layer 106 contains hydrophilic pendant tertiary alcohol and can be dissolved by a developing agent such as TMAH (tetra-methyl-ammonium hydroxide).

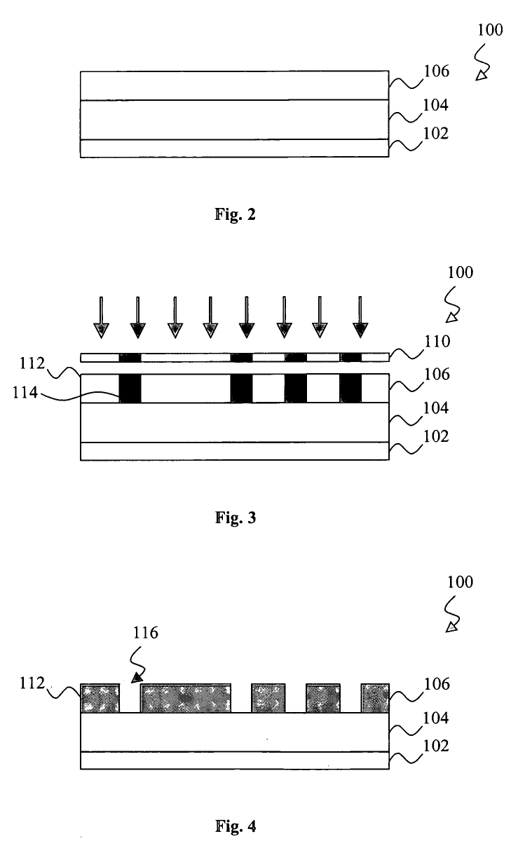

In step 14 and with additional reference to FIG. 3, a patterning process (e.g., an exposure process) is performed on the device 100. A mask 110, which in the present example is a cr-less mask, provides a pattern on the polymer layer 106. The exposure process results in a series of exposed areas 112 and non-exposed areas 114. As stated previously, the exposure process will not cause cross-linking (or will cause only minimal cross-linking) due to the composition of the polymer layer 106. The use of the cr-less mask with the negative photoresist of the polymer layer 106 may aid in hole printing in the underlying layer 104, as well as serving to minimize the MEF.

In the present example, a post exposure baking (PEB) process is performed on the polymer layer 106 after the exposure process. Following the exposure and PEB processes, the hydrophilic pendant tertiary alcohol forming the exposed areas 112 of the polymer layer 106 is chemically modified into lipophilic pendent olefin. This produces a polarity change in the polymer layer 106 and renders the exposed areas 112 of the polymer layer 106 insoluble (or largely insoluble) by a developer. The polarity change may also have the effect of reducing or eliminating the tendency of the polymer layer 106 to swell.

In step 16 and with additional reference to FIG. 4, a development step is performed on the device 100 after the device undergoes the PEB process. As illustrated in FIG. 4, the non-exposed areas 114 have been removed by a developer to form holes 116. It is noted that the dimensions of each of the holes 116 and the exposed areas 112 (which were not removed) are substantially defined by a corresponding area of the mask 110.

In step 18 and with additional reference to FIG. 5, the device 100 is heated (e.g., baked) at a predefined temperature (e.g., between approximately 130 and 180° C.) for a specific amount of time (e.g., between approximately 0.5 and 2 minutes). It is understood that the temperature, time, and other variables (e.g., pressure) may vary based on such factors as the chemical composition of the polymer layer 106. During the baking process, the exposed areas 112 of the polymer layer 106 may flow, and effectively improve the DOF as the holes 116 become smaller. The amount of flow may be regulated by controlling the temperature, duration, and/or other factors of the heating process, and may also be dependent on the chemical composition of the polymer layer 106.

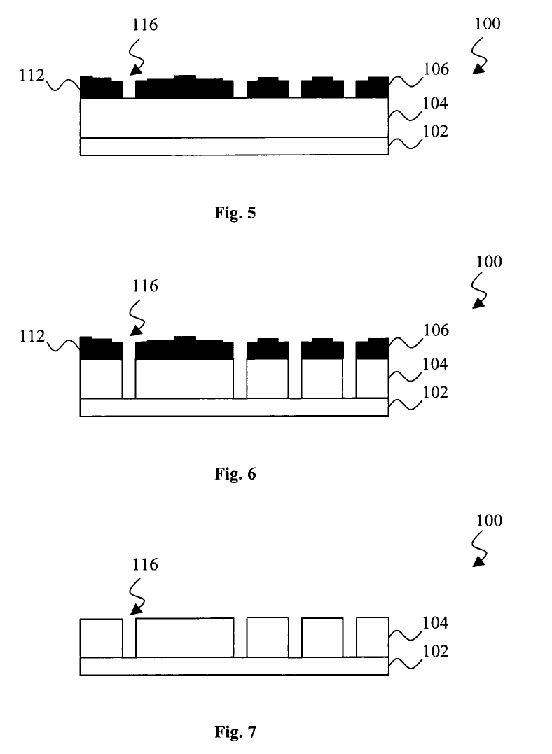

In step 20 and with additional reference to FIG. 6, an etching process is used to etch the underlying layer 104. As previously described, the chemical alteration of the polymer layer from hydrophilic pendent tertiary alcohol to lipophilic pendent olefin renders the polymer layer 106 insoluble or largely insoluble by a developer. Accordingly, the polymer layer 106 will be more resistant to etching than it was previously (e.g., in step 14), enabling the underlying layer 104 to be etched without totally removing the polymer layer 106 during the same etching process. For example, if the underlying layer 104 is a dielectric layer formed of a material such as silicon oxide, then the etching may include the use of process gases such as hydrofluoric (HF) acid or buffered hydrofluoric (BHF) acid at a temperature of approximately 0 to 100° C., a pressure of approximately 10 milli-torr to 200 milli-torr, and over a period of time between approximately 0.5 to 3 minutes. As the etching is controlled by the polymer layer 106 that has flowed to reduce the size of the holes 116, the holes etched in the underlying layer 104 will be smaller than the corresponding areas in the mask 110.

In step 20 and with additional reference to FIG. 7, the polymer layer 106 may be removed, exposing the etched underlying layer 104. The removal may be accomplished by oxygen or nitrogen dry etching or a developer such as EKC270-T (available from DuPont Electronic Technologies of California, USA) or by another process such as a planarization process (e.g., chemical mechanical planarization (CMP)).

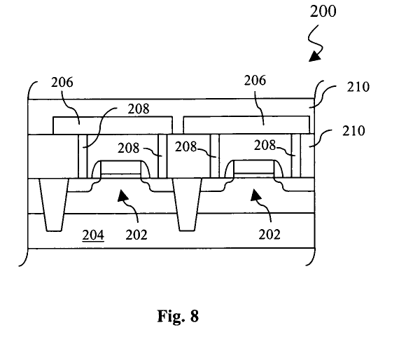

Referring to FIG. 8, illustrated is a sectional view of one embodiment of an integrated circuit 200 constructed according to aspects of the present disclosure. The integrated circuit 200 is one environment in which the semiconductor device 100 of FIGS. 2-7 may be implemented. For example, the integrated circuit 200 includes a plurality of vias used for vertical interconnections. The vias may be created by forming holes in a dielectric layer using the method 10 of FIG. 1 and then filling the holes with a conductive material. In the present example, the integrated circuit 200 includes metal oxide semiconductor field effect transistor (MOSFET) devices 202 formed on a substrate 204.

The substrate 204 may comprise any of a variety of semiconductors, including an elementary semiconductor, a compound semiconductor, or an alloy semiconductor. The elementary semiconductor may include materials such as silicon, germanium, and diamond. The compound semiconductor may include silicon carbide, gallium arsenic, indium arsenide, and indium phosphide. The alloy semiconductor may include silicon germanium, silicon germanium carbide, gallium arsenic phosphide, and gallium indium phosphide. The substrate may include an epitaxial layer. For example, the substrate may have an epitaxial layer overlying a bulk semiconductor. Furthermore, the substrate 204 may be strained for performance enhancement. For example, the epitaxial layer may comprise a semiconductor material different from those of the bulk semiconductor such as a layer of silicon germanium overlying a bulk silicon, or a layer of silicon overlying a bulk silicon germanium formed by a process including SEG. Furthermore, the substrate may comprise a SOI structure.

A source and drain of each MOSFET device 202 are connected to overlying metal lines 206 by means of vias 208. The vias 208 are formed through a dielectric layer 210. Additional interconnects (e.g., metal lines, vias, and contacts) may be used to couple the MOSFET devices to each other and/or to other portions of the integrated circuit 200. The interconnects may comprise multilayer interconnects having contact features and via features for vertical interconnections and metal lines for horizontal interconnections. The multilayer interconnects may comprise aluminum-based, tungsten-based, or copper-based materials, or combinations thereof. For example, a copper-based multilayer interconnect may include copper, copper alloy, titanium, titanium nitride, tantalum, tantalum nitride, tungsten, polysilicon, metal silicide, or combinations thereof.

The MOSFET devices 202 may each comprise a source and a drain, a gate electrode, a gate dielectric, and silicide features. The gate dielectric may include silicon oxide, silicon oxynitride, a high k material, and/or combinations thereof. The gate dielectric may comprise silicate such as HfSiO₄, HfSiON, HfSiN, ZrSiO₄, ZrSiON, and ZrSiN, or a metal oxide such as Al₂O₃, ZrO₂, HFO₂, Y₂O₃, La₂O₃, TiO₂, and Ta₂O₅. HY₂fSiON, HFSiN, ZrSiO₄, ZrSiON, and ZrSiN. The gate dielectric may be formed by thermal oxide, ALD, CVD, PVD, and/or other suitable processing techniques.

The gate electrodes may comprise polycrystalline silicon (poly-Si), poly-SiGe, metal such as Cu, W, Ti, Ru, Ta, and Hf; metal nitride such as TaSiN, TaN, TiN, WN, MoN, and HfN; metal oxide such as RuO₂ and IrO₂, combinations thereof; and/or other conductive materials. The gate electrodes may be formed by CVD, PVD, plating, ALD, and other suitable processes. The gate spacers may include silicon nitride, silicon oxide, silicon carbide, silicon oxynitride, or combinations thereof. The gate spacers may have a multilayer structure and may be formed by depositing a dielectric material and then anisotropically etching the material back.

A contact layer such as a silicide may be formed for reduced contact resistance and improved performance. The contact layer may include a metal silicide such as nickel silicide, cobalt silicide, tungsten silicide, tantalum silicide, titanium silicide, platinum silicide, erbium silicide, palladium silicide, or combinations thereof. In one example, silicide may be formed by a silicidation processing, referred to as self-aligned silicide (salicide).

The integrated circuit 300 may form all or a portion of a variety of devices. The devices 202 may include, but are not limited to, passive components such as resistors, capacitors, and inductors, active components such as MOSFETs, bipolar transistors, high voltage transistors, high frequency transistors, memory cells, or combinations thereof.

While the preceding description shows and describes one or more embodiments, it will be understood by those skilled in the art that various changes in form and detail may be made therein without departing from the spirit and scope of the present disclosure. For example, various steps of the described method may be executed in a different order or executed sequentially, combined, further divided, replaced with alternate steps, or removed entirely. In addition, various functions illustrated in the methods or described elsewhere in the disclosure may be combined to provide additional and/or alternate functions. Therefore, the claims should be interpreted in a broad manner, consistent with the present disclosure.

What is claimed is:

1. A method for manufacturing a portion of a semiconductor device, the method comprising:
forming a negative photoresist layer over an underlying layer, wherein the negative photoresist layer is soluble by a developer when formed;
patterning the negative photoresist layer using a chromium-less mask, wherein the patterning alters at least a portion of the negative photoresist layer so that the altered portion is not soluble by the developer;
developing the negative photoresist layer to form at least one opening in the negative photoresist layer, wherein the opening is formed by removing an unaltered portion of the negative photoresist layer; and
heating the negative photoresist layer, wherein the negative photoresist layer flows in response to the heating.

2. The method of claim 1 wherein the negative photoresist layer comprises hydrophilic pendant tertiary alcohol when formed.

3. The method of claim 2 wherein the patterning alters the hydrophilic pendant tertiary alcohol to lipophilic pendant olefin.

4. The method of claim 2 wherein the developer is an alcohol.

6. The method of claim 1 further comprising etching the underlying layer after heating the negative photoresist layer.

7. The method of claim 6 further comprising removing the negative photoresist layer after the etching.

8. The method of claim 7 wherein the negative photoresist layer is removed using a developer.

9. The method of claim 7 wherein the negative photoresist layer is removed using a chemical mechanical planarization process.

10. The method of claim 1 further comprising heating the patterned negative photoresist layer prior to the developing.

11. A method for semiconductor manufacturing comprising:
forming a polymer layer over an underlying layer, wherein the polymer layer is soluble by a developer when formed;
exposing the polymer layer using a cr-less mask to create a pattern of at least one exposed portion and one unexposed portion on the polymer layer, wherein the exposing alters a chemical property of the exposed portion so that it is not soluble by the developer;
removing the unexposed portion to create an opening in the polymer layer;
heating the exposed portion to make the exposed portion flow in order to narrow the opening; and
etching the underlying layer through the narrowed opening.

12. The method of claim 11 wherein the polymer layer comprises hydrophilic pendant tertiary alcohol when formed.

13. The method of claim 12 wherein the exposing alters the hydrophilic pendant tertiary alcohol to lipophilic pendant olefin.

14. The method of claim 11 further comprising removing the polymer layer after the etching.

15. The method of claim 14 wherein the polymer layer is removed using a developer.

16. The method of claim 14 wherein the polymer layer is removed using a chemical mechanical planarization process.

17. The method of claim 11 further comprising heating the polymer layer prior to removing the unexposed portion.

18. The method of claim 11 wherein forming the polymer layer includes depositing a polymer material using a spin-on coating process and baking the deposited material.
